(19) United States
(12) Patent Application Publication
(10) Pub. No.: US 2006/0002203 A1
(43) Pub. Date: Jan. 5, 2006

(54) Input device having activating means

(75) Inventors: Takashi Kondo, Tokyo (JP); Toshihiko Saito, Tokyo (JP); Kazunori Nakano, Tokyo (JP)

Correspondence Address: BRINKS HOFER GILSON & LIONE, P.O. BOX 10395, CHICAGO, IL, 60610, US

(73) Assignee: ALPS ELECTRIC CO., LTD.

(21) Appl. No.: 11/167,865

(22) Filed: Jun. 27, 2005

(30) Foreign Application Priority Data
Jul. 1, 2004 (JP) 2004-195158

(51) Int. Cl. G11C 29/00

(52) U.S. Cl. 365/200

(57) ABSTRACT

An activating section is bonded to the lower portion of an input section. When a face sheet is pushed by a finger or the like, the pushing force is transmitted to the interior of an input device, and an upper electrode comes into contact with a lower electrode so as to become conductive. A push signal (interrupting signal) generated at the conduction interrupts a CPU. The CPU activates the input section on the basis of the interrupting signal. Then, a sensor circuit of the input section detects coordinate positions of the finger or the like. That is to say, when the finger or the like does not push the face sheet, the input section is not activated and the sensor circuit does not perform a scan or the like. As a result, unnecessary power supply to the circuit is cut, and the power consumption can be reduced.

### BACKGROUND OF THE INVENTION

1. Field of the Invention

The present invention relates to input devices having an input section for detecting plane coordinates of positions during operations such as pushing an operational surface, and in particular, relates to input devices consuming lower amounts of power.

2. Description of the Related Art

Capacitive flat input devices are used in, for example, cellular phones as input devices for cursor movement such as menu selection or for handwriting, or as pointing devices of personal computers.

The capacitive flat input devices include operational surfaces formed of flat sheets or the like, and capacitances are varied when the surfaces of the sheets are operated by fingers or the like. Coordinate positions of the fingers on the operational surfaces can be detected by measuring the variations of the capacitances. According to this principle, coordinate data for moving cursors on display screens to desired positions can be obtained.

In Japanese Unexamined Patent Application Publication No. 2002-123363, one of such capacitive flat input devices is included in, for example, a remote controller of a television.

In Japanese Unexamined Patent Application Publication No. 2003-99185, one of such capacitive flat input devices reduced in thickness is used as a pointing device of a personal computer.

However, while the power is turned on, the capacitive flat input devices disclosed in Japanese Unexamined Patent Application Publication Nos. 2002-123363 and 2003-99185 always scan the variations of the capacitances with sensor circuits connected to the flat input devices even when the operational surfaces are not operated, resulting in an increase in power consumption.

In particular, remote apparatuses such as remote controllers use batteries as power sources, and usually do not have power switches for turning the power on or off. Accordingly, the remote apparatuses including the flat input devices keep scanning the variations of the capacitances of the flat input devices even when the remote apparatuses are not used (even when the operational surfaces are not operated). This leads to an increase in the power consumption of the batteries.

### SUMMARY OF THE INVENTION

Accordingly, it is an object of the present invention to provide an input device consuming lower amounts of power.

The input device having activating means according to the present invention includes a face sheet, the upper surface of the face sheet functioning as an operational surface; and an input section for detecting plane coordinates of an operational position on the operational surface, the input section being disposed under the face sheet. The input device is characterized in that the activating means is disposed on a surface of the input section remote from the face sheet, and detects the operation on the operational surface; and the input section is activated on the basis of an operating signal output from the activating means.

According to the present invention, the input section is activated on the basis of the operating signal output from the activating means only when the operational surface is operated. Thus, the power consumption can be reduced compared with the known technology.

According to the present invention, it is preferable that the activating means and the input section be connected to controlling means, and that the controlling means output an activating signal to the input section in response to the operating signal output from the activating means.

Furthermore, according to the present invention, it is preferable that the activating means include a switch portion, that the switch portion enter an input state so as to output a push signal when the operational surface is pushed, and that the input section be activated on the basis of the push signal.

According to the description above, the structure of the activating means can be simplified. In particular, according to the present invention, there is no need to detect which switch portion was pushed, for example, and only an input state of the switch portion is required. Thus, the switching circuit can be simplified.

According to the present invention, it is preferable that the switch portion be a plurality of switch portions.

When the input device includes the plurality of switch portions, an operator can push any position on the face sheet of the input section such that one of the switch portions enters an input state. Thus, a push signal is output, and the input section can easily be activated.

Furthermore, according to the present invention, it is preferable that the activating means include an upper sheet having an upper electrode disposed on the lower surface of the upper sheet, and a lower sheet having a lower electrode disposed on the upper surface of the lower sheet, the lower sheet opposing the upper sheet with a predetermined spacing therebetween; and that the upper electrode and the lower electrode paired in the height direction form the switch portion.

Alternatively, according to the present invention, it is preferable that the activating means include a flexible plate and a detecting board, that a projection having a conductive element on the tip be disposed on the plate, that a pair of electrodes be disposed on the detecting board, and that the conductive element and the pair of electrodes opposing in the height direction form the switch portion.

With the above-described detecting means, the activating means can reliably enter an input state even with a small pushing force, and as a result, the input section can easily be activated.

According to the present invention, it is preferable that the input section be a capacitive sensor. Furthermore, according to the present invention, the power consumption can be appropriately reduced even when the input device is included in a remote apparatus.

### BRIEF DESCRIPTION OF THE DRAWINGS

FIG. 1 is a perspective view illustrating an electronic apparatus including an input device according to the present invention;

FIG. 2 is a cross-sectional view of the input device according to an embodiment of the present invention taken along line II-II in FIG. 1;

FIG. 3 is a cross-sectional view taken at the same position as FIG. 2 when the input device shown in FIG. 2 is pushed by a finger or the like;

FIG. 4 is a block diagram illustrating operations of the input device;

FIG. 5 is an exploded perspective view illustrating an activating section according to a modification of the first embodiment of the present invention; and

FIG. 6 is a cross-sectional view of an input device according to a second embodiment of the present invention taken at the same position as FIG. 2.

### DESCRIPTION OF THE PREFERRED EMBODIMENTS

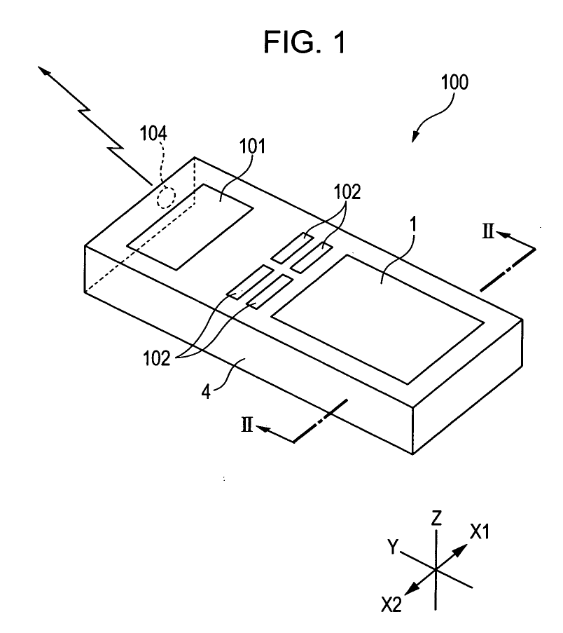

As shown in FIG. 1, an input device 1 according to the present invention is included in an electronic apparatus 100 having no power switch for turning the power on or off and driven by a battery or the like. The electronic apparatus 100 is, for example, a remote apparatus such as a remote controller.

The electronic apparatus 100 includes a display 101 for displaying various images such as menu panels, a plurality of buttons (push switches) 102, and the input device 1. Cursor movement such as menu selection on the display 101 is performed in response to operations on the input device 1, and selected information is sent from a transmitting section 104 to external receiving apparatuses.

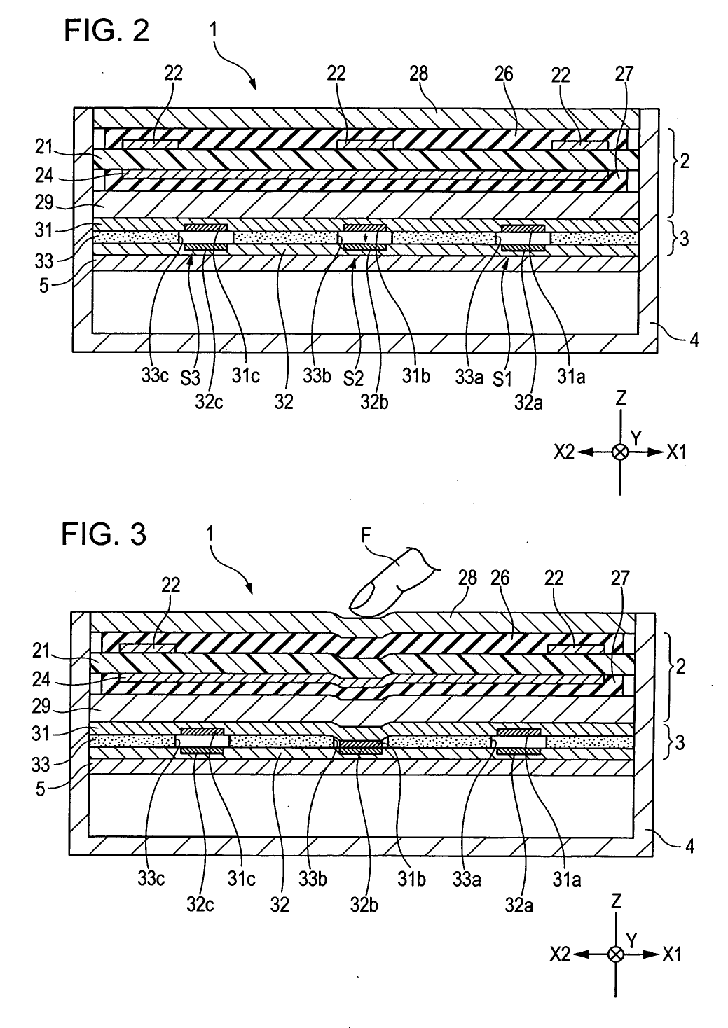

As shown in FIG. 2, the input device 1 includes an input section 2 and an activating section 3. The lower surface of a control circuit board 29 of the input section 2 and the upper surface of an upper sheet 31 of the activating section 3 are bonded together with a bonding member such as an adhesive, and the activating section 3 is bonded to a base 5 composed of, for example, a glass epoxy resin with an adhesive or the like. Thus, the input section 2 and the activating section 3 are fixed to a casing 4.

The input section 2 is a so-called capacitive flat input device, and specifically, a capacitive type known as GLIDEPOINT®.

In the input section 2, a plurality of X electrodes 22 is formed on the upper surface of a film substrate 21 composed of, for example, a synthetic resin such as polyethylene terephthalate (PET), and a plurality of Y electrodes 24 is formed on the lower surface of the film substrate 21. The X electrodes 22 and the Y electrodes 24 are arranged in a grid, and covered with insulating layers 26 and 27, respectively. A face sheet 28 is disposed on the insulating layer 26, and the upper surface of the face sheet 28 functions as an operational surface.

As shown in FIG. 2, the control circuit board 29 is disposed on the lower surface of the insulating layer 27. The control circuit board 29 includes a sensor circuit containing, for example, a central processing unit (CPU) and an amplifier for amplifying outputs of detected signals (not shown) on a surface remote from the film substrate 21 (the lower surface).

In the input section 2, through holes (not shown) for electrically connecting the X electrodes 22 and the Y electrodes 24 are formed in the film substrate 21, insulating layer 27, and the control circuit board 29; and coordinate signals based on the capacitances detected at the X electrodes 22 and the Y electrodes 24 are sent to the sensor circuit.

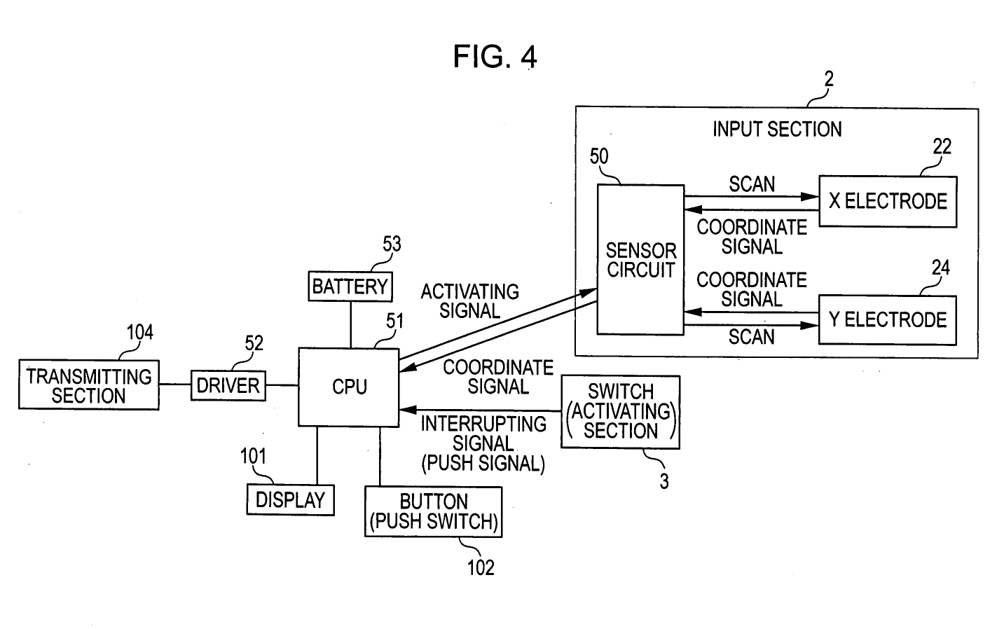

As shown in FIG. 4, the detected coordinate signals are amplified by the amplifier contained in a sensor circuit 50, converted into digital signals at an analog-to-digital (A/D) converter, and sent to a CPU 51. Subsequently, the coordinate signals are sent from the CPU 51 to the transmitting section 104 via a driver 52, and then sent from the transmitting section 104 to external receiving apparatuses.

As shown in FIG. 3, when an electric conductor F such as a finger pushes the operational surface of the face sheet 28 of the input device 1, part of electric lines of force flowing from the X electrodes 22 to the Y electrodes 24 is absorbed by the finger or the like of an operator at the X electrodes 22 and the Y electrodes 24. As a result, the electric lines of force absorbed by the Y electrodes 24 are reduced, and the capacitances are varied. The coordinate positions of the electric conductor F such as a finger are detected on the basis of current outputs varied in response to these capacitances. This detection is performed by the CPU 51 or the sensor circuit 50 mounted on the backside of the control circuit board 29.

As shown in FIG. 2, the activating section 3 is disposed on the surface of the input section 2 remote from the face sheet 28 (the lower surface).

In the activating section 3, the upper sheet 31 and a lower sheet 32 opposing the upper sheet 31 are fixed to each other with a sheet spacer 33 interposed therebetween. Both the upper sheet 31 and the lower sheet 32 are composed of a flexible material such as a PET resin or a polyimide resin, and the spacer 33 is composed of a binding material. Alternatively, the sheets 31 and 32 and the spacer 33 all may be composed of a PET resin or the like, and may be fixed to each other.

Circular upper electrodes 31a, 31b, and 31c composed of a metallic material such as copper or silver are formed on the surface of the upper sheet 31 facing the lower sheet 32, and circular lower electrodes 32a, 32b, and 32c composed of a metallic material such as copper or silver are formed on the surface of the lower sheet 32 facing the upper sheet 31. Circular though holes 33a, 33b, and 33c having a diameter larger than the external diameters of the upper and lower electrodes are formed in the spacer 33. These upper and lower electrodes opposing each other in the height direction (Z direction) form switch portions S1, S2, and S3, respectively. In FIG. 2, only three switch portions S1, S2, and S3 are shown. However, a number of switch portions are formed over the X-Y plane of the input device 1 of the electronic apparatus 100 in practice.

Distinctive features of the present invention will now be described. As shown in FIG. 2, when the operational surface of the face sheet 28 of the input device 1 is not pushed by a finger or the like, the upper electrodes 31a, 31b, and 31c and the lower electrodes 32a, 32b, and 32c of the activating section 3 oppose each other with a predetermined spacing therebetween, and switching signals (operating signals) are not output. At this time, the sensor circuit 50 connected to the input section 2 shown in FIG. 4 does not receive power from a battery 53, and is not activated. In other words, the sensor circuit 50 in the state shown in FIG. 2 does not scan coordinate signals of the X electrodes 22 and the Y electrodes 24 of the input section 2.

As shown in FIG. 3, when the operational surface of the face sheet 28 of the input device 1 is pushed by the electric conductor F such as a finger, the pushing force is transmitted to the interior of the input device 1, and the control circuit board 29 of the input section 2 is deformed downward. Then, the upper sheet 31 of the activating section 3 bonded to the control circuit board 29 is also deformed downward, and the upper electrode 31b comes into contact with the lower electrode 32b. In this manner, the electrodes are connected to each other, and the operating signals (push signals) are output.

As shown in FIG. 4, the push signals output from the activating section 3 interrupt the CPU 51. The CPU 51 sends an activating signal for activating the input section 2 to the sensor circuit 50 in response to the interrupting signals. The sensor circuit 50 then receives power from the battery 53, and is activated.

In this manner, the sensor circuit 50 is activated on the basis of the activating signal from the CPU 51, and scans and detects the coordinate signals output from the X electrodes 22 and the Y electrodes 24.

The detected coordinate signals are, for example, converted into digital signals at the A/D converter contained in the sensor circuit 50, and sent to the CPU 51. The coordinate signals are then sent from the CPU 51 to the transmitting section 104 via the driver 52, and received by external receiving apparatuses.

In this manner, according to the present invention, the input section 2 is activated on the basis of the push signals output from the activating section 3. In other words, the input section 2 is not activated unless the push signals are not output. That is to say, when the electric conductor F such as a finger does not push the operational surface of the face sheet 28 as shown in FIG. 2, the input section 2 is not activated, and the sensor circuit 50 does not perform a scan. Thus, unnecessary power supply to the circuit is cut, and the power consumption of the battery 53 can be reduced.

Moreover, the CPU 51 controls the activation of the input section 2 on the basis of the push signals from the activating section 3 as shown in FIG. 4. This leads to an easy circuit design.

According to the control by the CPU 51, for example, the activated input section 2 can easily be deactivated when the coordinate signals are not detected from the input section 2 within a predetermined period of time by cutting the power supply to the input section 2. Also, the input section 2 can be activated depending on the amplitudes of the outputs from the activating section 3. For example, when the outputs from the activating section 3 do not exceed a threshold level, the outputs are determined as misoperations, and the input section 2 is not activated. In this case, the input section 2 can be activated only when the outputs exceed the threshold level.

The input section 2 is activated when any one of the switch portions S1, S2, and S3 of the activating section 3 is pushed. However, there is no need to detect which switch portion was pushed at this time, and only a push signal output from the activating section 3 is required. Thus, the circuit can be simplified by, for example, connecting the switch portions S1, S2, and S3 in series.

Alternatively, the pushed switch portion may be detected such that the CPU 51 performs a predetermined control when a predetermined switch portion is pushed. For example, when a menu panel is shown on the display 101, an operator operates the input section 2 so as to move a cursor onto an icon displayed in the menu panel. When one of the switch portions S1, S2, and S3 is pushed, a push signal is output, and the CPU 51 outputs a command signal for opening the icon.

In this case, the switch portions S1, S2, and S3 must be wired separately, or a change-over switch or the like for detecting the pushed switch portion must be prepared.

It is preferable that marks indicating the positions of the switch portions S1, S2, and S3 be printed on the operational surface of the face sheet 28.

The activating section 3 shown in FIG. 2 is a so-called membrane switch. Therefore, the upper electrodes and the lower electrodes reliably come into contact with each other and become conductive even when the input section 2 is pushed with a small pushing force. As a result, the input device 1 can easily be activated.

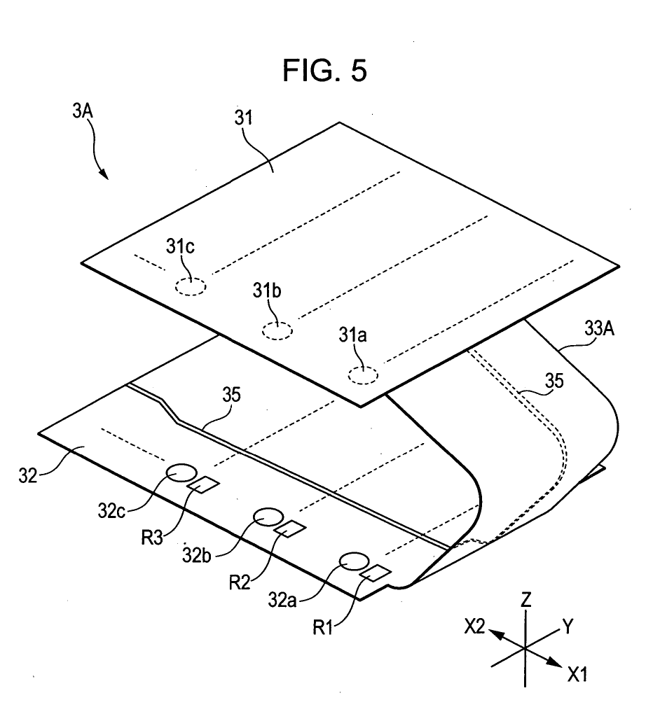

FIG. 5 is an exploded perspective view illustrating an activating section according to a modification of the first embodiment of the present invention. The spacer is omitted, and the arrangement of a plurality of upper electrodes 31a, 31b, and 31c formed on an upper sheet 31 and a plurality of lower electrodes 32a, 32b, and 32c formed on a lower sheet 32 in the X-Y plane is shown by the dotted lines on both sheets.

In this modification, the structure of the input device is the same as that shown in FIG. 2 except for an activating section 3A.

The activating section 3A includes the upper sheet 31 and the lower sheet 32 linked together via a flexible sheet 33A composed of a flexible resin such as a PET resin or a polyimide resin.

The upper electrodes 31a, 31b, and 31c formed on the upper sheet 31 are connected in series by lead wires, and are connected to an extension pattern 35 composed of a metallic material such as copper and silver. The extension pattern 35 is exposed on the surfaces of the upper sheet 31 and the lower sheet 32 opposing each other, and is preferably insulated so as to avoid a contact. The extension pattern 35 is extended to the exterior of the activating section 3A via the flexible sheet 33A and the lower sheet 32. Resistors R1, R2, and R3 are printed adjacent to the respective lower electrodes of the lower sheet 32. Therefore, when the upper electrodes and the lower electrodes come into contact with each other and become conductive, a voltage output by this conduction is detected.

In this modification, all of the upper sheet 31, the lower sheet 32, and the flexible sheet 33A are composed of the same flexible material such as a PET resin or a polyimide resin. That is to say, the activating section 3A is produced by forming the upper sheet 31 and the lower sheet 32 linked to the flexible sheet 33A from the same material, and then by bending the flexible sheet 33A such that the upper sheet 31 and the lower sheet 32 oppose each other as shown in FIG. 5. Thus, the activating section 3A can easily be produced.

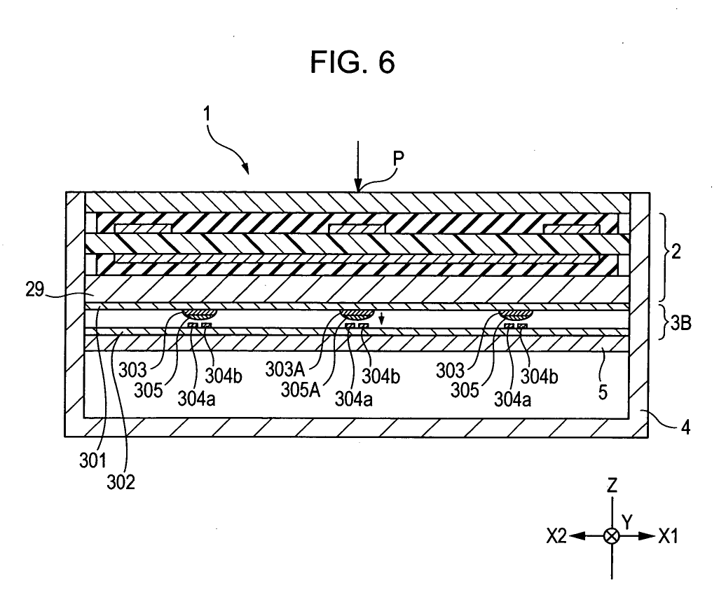

FIG. 6 is a cross-sectional view of an input device according to a second embodiment of the present invention taken at the same position as FIG. 2. In this embodiment, the structure of the input device is the same as that of the first embodiment except for an activating section 3B. In contrast to the first embodiment, the activating section 3B is not a so-called membrane switch.

The activating section 3B includes a plate 301 of a film composed of a synthetic resin such as a PET resin and a detecting board 302.

A plurality of projections 303 composed of, for example, an ultraviolet (UV) curable resin is printed on the backside of the plate 301. In FIG. 6, only three projections 303 are shown. However, a number of projections are formed over the X-Y plane of an input section 1 of an electronic apparatus 100 in practice.

Pairs of electrodes 304a and 304b are disposed on the upper surface of the detecting board 302 with a predetermined spacing therebetween at positions opposing the respective projections 303. Moreover, a conductive element 305 (electrode) containing, for example, carbon is disposed on each tip of the projections 303 formed on the plate 301. In this embodiment, the conductive element 305 and the pair of electrodes 304a and 304b form a switch portion.

Operations of an input device 1 according to this embodiment are similar to those according to the first embodiment. When the input device 1 is pushed by a finger or the like at, for example, a position P, the pushing force is transmitted to the interior of the input device 1, and a control circuit board 29 of an input section 2 is deformed downward. Then, the plate 301 of the activating section 3B bonded to the control circuit board 29 is also deformed downward, and a conductive element 305A disposed on the tip of a projection 303A comes into contact with both the electrodes 304a and 304b opposing the conductive element 305A so as to become conductive. At this conduction, a push signal generated at the switch portion interrupts a CPU 51 included in the input section 2. The CPU 51 activates the input section 2 on the basis of this interrupting signal.

In this manner, the input section 2 is activated on the basis of the push signals output from the activating section 3B. In other words, the input section 2 is not activated unless the push signals are not output. That is to say, when the electric conductor such as a finger does not push the operational surface of the face sheet 28, the input section 2 is not activated, and the sensor circuit 50 does not perform a scan. Thus, unnecessary power supply to the circuit is cut, and the power consumption can be reduced.

According to the activating section 3B of this embodiment, the conductive elements disposed on the tips of the projections come into contact with the respective pairs of electrodes opposing the conductive elements and become conductive even when the input section 2 is pushed with a small pushing force as in the case for the first embodiment. As a result, the input device 1 can easily be activated.

In contrast to the description above, the input device according to the present invention may include only one switch portion. However, it is preferable that the input device include the plurality of switch portions as above. When the input device includes the plurality of switch portions, an operator can push any position on the face sheet of the input section such that one of the switch portions enters an input state. Thus, a push signal is output, and the input section can easily be activated.

According to the present invention, the input device 1 is included in a remote apparatus such as a remote controller shown in FIG. 1, and powered by the battery 53 or the like without a power switch for turning the power on or off. However, the input device 1 may also be included in a remote apparatus with a power switch as long as the power is supplied by the battery 53 or the like.

Furthermore, the present invention is applicable not only to remote controllers but also electronic apparatuses such as cellular phones and personal computers.

The activating section 3 includes the plurality of switch portions, and outputs the push signals when the operational surface is pushed and the switch portions enter an input state. However, the activating section 3 may have a structure other than this.

1. An input device having activating means comprising:
a face sheet, an upper surface of the face sheet functioning as an operational surface; and
an input section for detecting plane coordinates of an operational position on the operational surface, the input section being disposed under the face sheet, wherein
the activating means is disposed on a surface of the input section remote from the face sheet, and detects an operation on the operational surface; and
the input section is activated on the basis of an operating signal output from the activating means.

2. The input device according to claim 1, wherein
the activating means and the input section are connected to controlling means; and
the controlling means outputs an activating signal to the input section in response to the operating signal output from the activating means.

3. The input device according to claim 1, wherein
the activating means comprises a switch portion;
the switch portion enters an input state so as to output a push signal when the operational surface is pushed; and
the input section is activated on the basis of the push signal.

4. The input device according to claim 3, wherein
said switch portion comprises a plurality of switch portions.

5. The input device according to claim 3, wherein
the activating means comprises
an upper sheet having an upper electrode disposed on a lower surface of the upper sheet; and
a lower sheet having a lower electrode disposed on an upper surface of the lower sheet, the lower sheet opposing the upper sheet with a predetermined spacing therebetween; and
the upper electrode and the lower electrode paired in a height direction forms the switch portion.

6. The input device according to claim 3, wherein
the activating means comprises a flexible plate and a detecting board;
a projection having a conductive element on a tip is disposed on the plate;
a pair of electrodes is disposed on the detecting board; and
the conductive element and the pair of electrodes opposing in a height direction forms the switch portion.

7. The input device according to claim 1, wherein
the input section is a capacitive sensor.

8. The input device according to claim 1, wherein
the input device is included in a remote apparatus.
